(19) United States
(12) Patent Application Publication
(10) Pub. No.: US 2002/0075653 A1
(43) Pub. Date: Jun. 20, 2002

(54) Heat sink

(76) Inventor: Shih-Jen Lin, Taipei City (TW)

Correspondence Address: BACON & THOMAS, PLLC, 625 SLATERS LANE, FOURTH FLOOR, ALEXANDRIA, VA, 22314

(21) Appl. No.: 09/993,477

(22) Filed: Nov. 27, 2001

(30) Foreign Application Priority Data
Dec. 19, 2000 (TW) 089222002
Aug. 30, 2001 (TW) 089222002A01

(51) Int. Cl. H05K 7/20

(52) U.S. Cl. 361/703

(57) ABSTRACT

A heat sink having a flat base, a plurality of upright radiation fins upwardly extended from the top sidewall of the flat base and arranged in parallel, a plurality of elongated air passageways defined in between the upright radiation fins, and a wave-like top side formed of the topmost edges of the upright radiation fins and adapted for causing the fan-induced axial flow of air to pass through the air passageways at different speeds for causing convection currents.

### BACKGROUND OF THE INVENTION

The present invention relates to a CPU cooling structure and, more specifically, to a heat sink adapted for dissipating heat from a CPU or the like efficiently.

Following fast development of computer technology, a variety of advanced computers of high operation speed have been continuously disclosed. During the operation of the CPU of a computer, much heat is produced, and produced heat must be quickly carried away from the CPU, enabling the CPU to work under the environment of acceptable working temperature level. Various heat sinks have been disclosed for this purpose. FIG. 7 shows a heat sink according to the prior art. This structure of heat sink comprises a flat base, and a plurality of upright radiation fins upwardly extended from the top sidewall of the flat base and arranged in parallel. This design of heat sink is still not satisfactory in function. According to this design of heat sink, the upright radiation fins have an equal height. When used with an axial-flow fan, the induced axial flow of current is concentrated at the center area of the heat sink, resulting in low efficiency in dissipation of heat.

### SUMMARY OF THE INVENTION

The present invention has been accomplished to provide a heat sink, which eliminates the aforesaid drawback. It is one object of the present invention to provide a heat sink, which achieves a high performance. It is another object of the present invention to provide a heat sink, which is inexpensive to manufacture. According to the present invention, the heat sink comprises a flat base, a plurality of upright radiation fins upwardly extended from the top sidewall of the flat base and arranged in parallel, a plurality of elongated air passageways defined in between the upright radiation fins, and a wave-like top side formed of the topmost edges of the upright radiation fins and adapted for causing the fan-induced axial flow of air to pass through the air passageways at different speeds for causing convection currents. Because the heat sink have a wave-like top side, the fan-induced axial flow of air from the fan above the heat sink forms into currents of air of different speeds when touching different portions of the wave-like top side of the heat sink. Because currents of air pass through the air passageways at different speeds, convection currents are produced to carry heat away from the heat sink. According to tests made on a heat sink of the present invention and the aforesaid prior art heat sink under the use of a 60×60×25 cooling fan at 4200r.p.m, the heat dissipation efficiency of the prior art heat sink was 0.42(C°/W), and the heat dissipation efficiency of the present invention was 0.48(C°/W).

### BRIEF DESCRIPTION OF THE DRAWINGS

FIG. 1 is an exploded view of a CPU cooling structure constructed according to the present invention.

FIG. 2 is an assembly view of the CPU cooling structure shown in FIG. 1.

FIG. 3 is a schematic side view of the present invention showing strong currents of air and weak currents of air produced at the top of the upright radiation fins during operation of the fan.

FIG. 4 is a schematic drawing showing the flowing directions of different speeds of currents of air according to the present invention.

FIG. 5 is a schematic drawing showing the circulation of convection currents through the heat sink according to the present invention.

FIG. 6 is a perspective view of an alternate form of the heat sink according to the present invention.

FIG. 7 is a perspective view of a heat sink constructed according to the prior art.

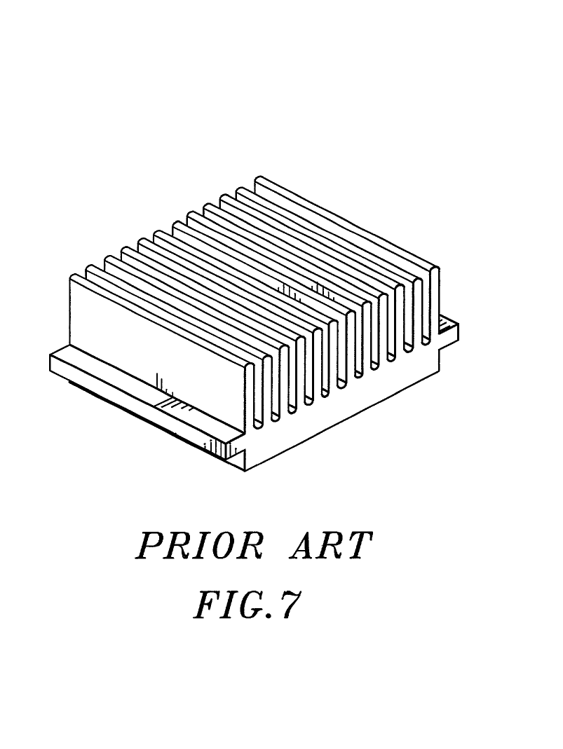

### DETAILED DESCRIPTION OF THE PREFERRED EMBODIMENT

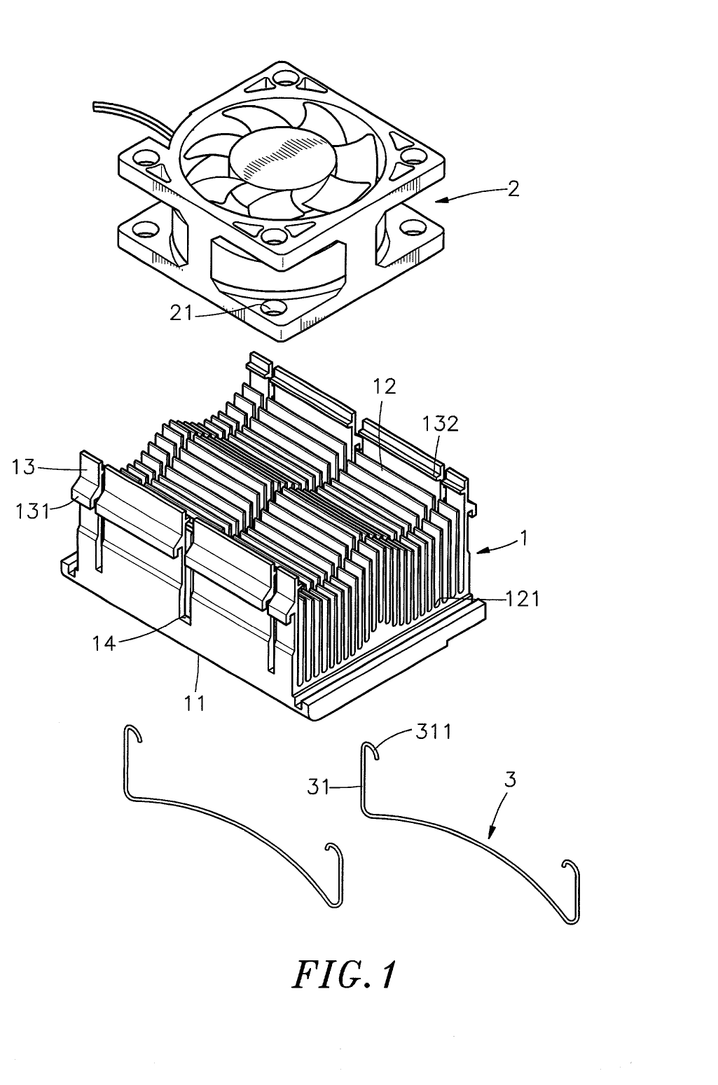

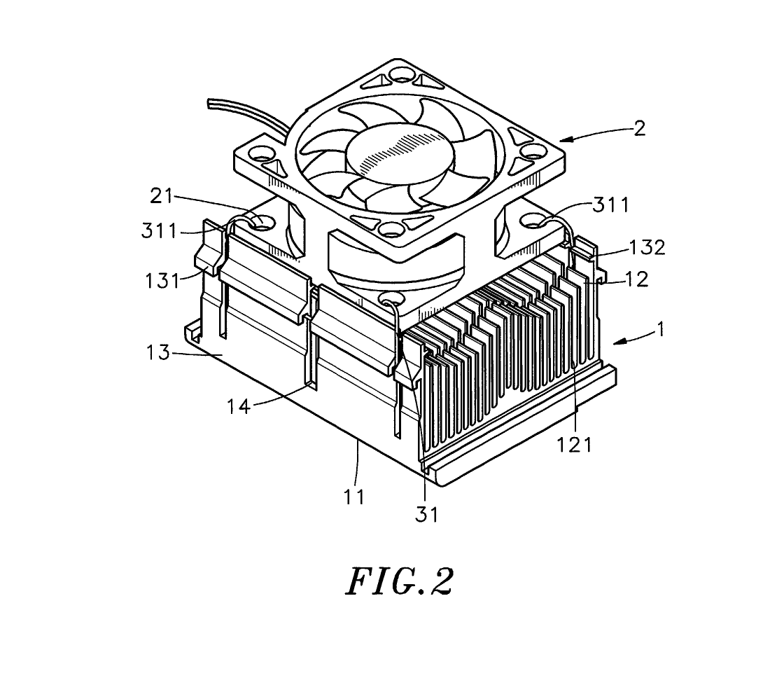

Referring to FIGS. 1 and 2, a heat sink 1 is mounted on the CPU 41 of a motherboard 4, a fan 2 is fastened to the heat sink 1 by two retaining wire rods 3. The heat sink 1 comprises a flat base 11 disposed in close contact with the top sidewall of the CPU 41 of the motherboard 4, a plurality of upright radiation fins 12 perpendicularly upwardly extended from the top sidewall of the flat base 11 and arranged in parallel, and a plurality of elongated air passageways 121 respectively defined between each two adjacent upright radiation fins 12. The elongated air passageways 121 each have a convex bottom side curved outwards in transverse direction. The first and last upright radiation fins 13 each have a horizontal retaining flange 131 outwardly protruded from the respective outer sidewall, and a horizontal bearing flange 132 protruded from the respective inner sidewall. The fan 2 is supported on the horizontal bearing flanges 132 of the first and last upright radiation fins 13, having a plurality of mounting holes 21. The retaining wire rods 3 are respectively secured to the horizontal retaining flanges 131 of the first and last upright radiation fins 13, each having two arms 31 respectively extended out of the ends of the respective horizontal retaining flanges 131 and secured to the fan 2. The arms 31 of the retaining wire rods 3 are respectively terminating in a respective hooked portion 311 respectively hooked in the mounting holes 21 of the fan 2. Further, the upright radiation fins 12 have different heights, and are so arranged to provide a wave-like top side. The upright radiation fins 12 can also be so arranged to provide a wave-like front side and a wave-like rear side. Further, the first and last upright radiation fins 13 are the highest upright radiation fins. The upright radiation fins 12 further have vertical slots 14 for the passing of air among the air passageways 121. According to the embodiment shown in FIGS. 1 and 2, the wave-like top side of the heat sink 1 (which is formed of the top side edges of the upright radiation fins 12) shows two substantially U-shaped waves respectively curved inwards and a wave peak at the connecting area between the two U-shaped waves.

Referring to FIGS. from 3 through 6, during running of the CPU 41, heat is transferred from the CPU 41 to the upright radiation fins 12 of the heat sink 1 through the flat base 11, and the fan 2 ceaselessly causes an axial flow of air C spirally rotated downwards toward the air passageways 121 in between the upright radiation fins 12 in clockwise direction. When the axial flow of air C moving to the upright radiation fins 12, a part of the axial flow of air C touches the upwardly curved portions of the wave-like top side of the heat sink 1, forming into strong currents of air A, and a part of the axial flow of air C touches the downwardly curved portions of the wave-like top side of the heat sink 1, forming into weak currents of air B. The strong currents of air A and the weak currents of air B strike against one another at different speeds, thereby causing convection currents to be produced and guided out of the heat sink 1 through the air passageways 121 and the vertical slots 14 at a high speed, and therefore heat is efficiently carried away from the CPU 41.

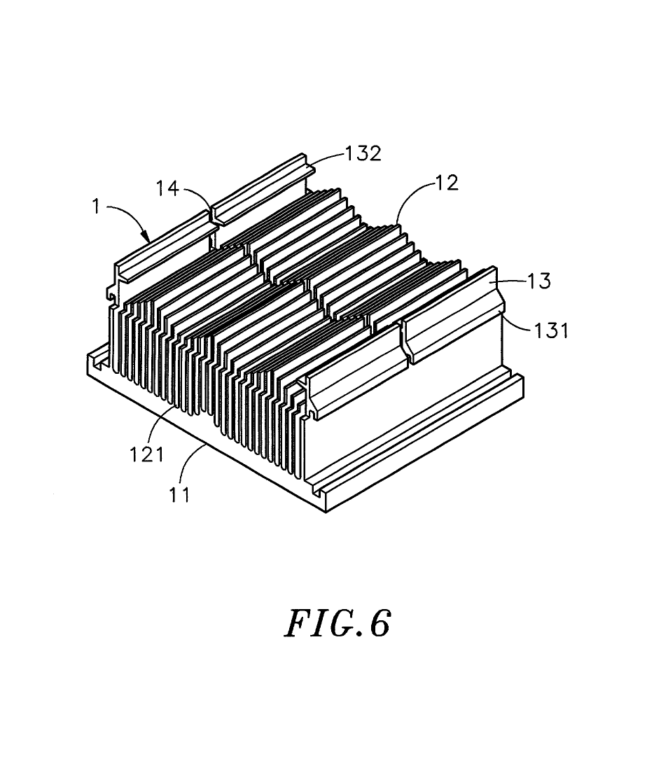

FIG. 6 is a perspective view of an alternate form of the heat sink 1 according to the present invention. According to this alternate form, the wave-like top side of the heat sink 1 shows three continuous waves each having a peak.

Further, the fabrication of the present invention can be achieved by means of conventional techniques. For example, the heat sink 1 can be extruded from aluminum in unity, and then properly cut subject to the desired dimensions. Because the heat sink 1 can be made in unity by means of conventional techniques without creating special molds for the production, the manufacturing cost of the heat sink 1 is not high.

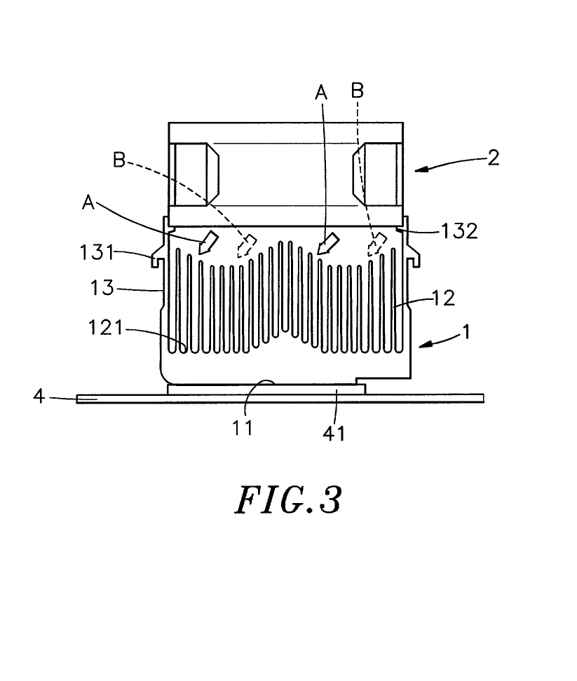

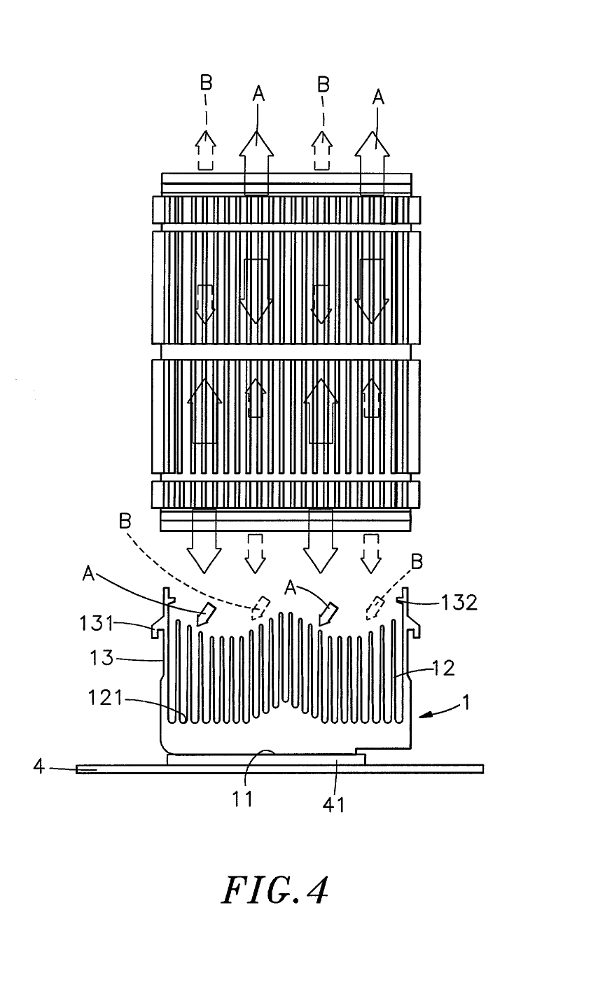

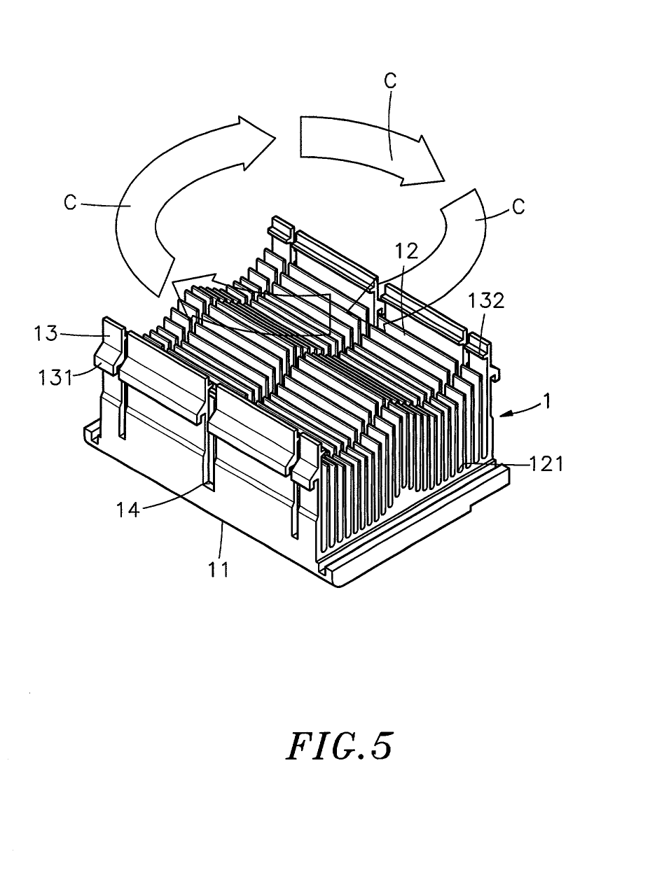

A prototype of heat sink has been constructed with the features of the annexed drawings of FIGS. 1-6. The heat sink functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A heat sink comparing comprising a flat base, a plurality of upright radiation fins upwardly extended from a top sidewall of said flat base and arranged in parallel, and a plurality of elongated air passageways defined in between said upright radiation fins, wherein said upright radiation fins have different heights, and the topmost edges of said upright radiation fins form a wave-like top side of the heat sink.

2. The heat sink as claimed in claim 1, wherein said upright radiation fins include two highest side radiation fins disposed at two sides, said highest side radiation fins each having a horizontal bearing flange protruded from an inner sidewall thereof and adapted for supporting a cooling fan.

3. The heat sink as claimed in claim 2, wherein said highest side radiation fins each have a horizontal retaining flange outwardly protruded from an outer sidewall thereof and adapted for holding a respective retaining wire rod for securing a fan to the horizontal bearing flanges of said highest side radiation fins.

4. The heat sink as claimed in claim 1, wherein said upright radiation fins each have a plurality of vertical slots in communication with said air passageways.

5. The heat sink as claimed in claim 1, wherein said elongated air passageways each have a convex bottom side curved outwards in transverse direction.

6. The heat sink as claimed in claim 1 wherein said wave-like top side comprises two substantially U-shaped waves respectively curved inwards and connected together, and a peak at the connecting area between said two U-shaped waves.

7. The heat sink as claimed in claim 1 wherein said wave-like top side comprises a series of waves respectively curved outwards, said waves each having a peak.
